(19) United States
(12) Patent Application Publication
(10) Pub. No.: US 2008/0025361 A1
(43) Pub. Date: Jan. 31, 2008

(54) Linear diode-laser array with series-connected emitters

(76) Inventors: John H. Jerman, Palo Alto, CA (US); Luis A. Spinelli, Sunnyvale, CA (US)

Correspondence Address: STALLMAN & POLLOCK LLP, 353 SACRAMENTO STREET, SUITE 2200, SAN FRANCISCO, CA, 94111, US

(21) Appl. No.: 11/488,986

(22) Filed: Jul. 19, 2006

(51) Int. Cl. H01S 5/00

(52) U.S. Cl. 372/50.12

(57) ABSTRACT

A longitudinal diode-laser array includes a plurality of diode-laser emitter groups. The emitter groups are mounted on corresponding electrical contacts electrically isolated from each other on a dielectric carrier. The emitter groups are cut from a conventionally formed diode-laser bar bonded to the carrier. The emitter-groups are connected together in electrical series via the electrically isolated electrical contacts. This provides that the diode-laser array can be operated at a lower current than would be required to operate the conventional diode-laser bar wherein the plurality of emitters must be connected in parallel.

### TECHNICAL FIELD OF THE INVENTION

The present invention relates in general to diode-laser arrays. The invention relates to linear arrays of edge-emitting diode-lasers.

### DISCUSSION OF BACKGROUND ART

Linear arrays of edge-emitting diode-lasers are commonly referred to as diode-laser bars. A diode-laser (edge-emitting semiconductor laser) bar usually includes a plurality of individual diode-lasers (emitters) distributed along a “bar” of comprising a plurality of semiconductor layers epitaxially grown on an electrically conductive semiconductor substrate. Such a bar usually has a length of about 100 millimeters (mm), a width of between about 1 mm and 1.5 mm, and a thickness of between about 100 micrometers (μm) and 300 μm. The emitters of the bar are formed in the epitaxial layers. In a diode-laser bar configured to deliver near infrared radiation with a power of about 1 Watt (W) per emitter or more, the width of the emitters is typically between about 50 μm and 200 μm. Usually, the wider the emitter the higher the power output of an individual emitter. The number of emitters in a bar is determined by the length of the bar, the width of the emitters, and the spacing therebetween. Nineteen emitters per bar is not an uncommon number of emitters per bar.

The width of the emitters is defined, among other factors, by the width of an electrical contact (stripe) formed on top of the epitaxially grown layers of the bar. Electrical contacts are made to the bar using the semiconductor substrate as an electrode common to all of the emitters (typically the n-type side of the diode-laser) and via the contact stripe on the epitaxially grown layers of the bar (typically the p-type side of the diode-laser). In this typical connection method, the substrates of the diode-lasers are effectively electrically connected in parallel.

Each emitter delivers output radiation from an emitting region in the edge of the diode-laser bar. Each emitting region has a width corresponding to about the width of the electrode-stripe width and has a height of between about 1 and 2 μm. This height is determined, inter alia, by the thickness of epitaxial layers forming what is usually termed an active region of the emitter. The emitters are characterized as having a slow axis in the width direction of the emitters and the slow axes of the emitters are aligned about co-linear with each other, parallel to the length of the diode-laser bar. The emitters have a fast-axis perpendicular to the length of the diode-laser bar. Radiation is emitted in a direction (along a propagation axis) perpendicular to the fast and slow axes.

A typical diode-laser emitter designed to emit light in the NIR may have a forward voltage drop of about 1.8V at a forward current of about 2.5 Ampéres (A). Nineteen such emitters operating in parallel will have the same forward voltage drop as any one of the emitters, but may require 50 amps or more to drive all of the emitters. Such a high current places significant demands on an electrical power supply used to supply the drive current and voltage, and on electrical connections to the diode bar.

There is a need to provide a linear array of diode-laser emitters that does not require the high drive current of typical of commercially available high-power diode-laser bars. The array should be manufacturable without significantly changing the way in which a diode-laser bar is presently manufactured.

### SUMMARY OF THE INVENTION

In one aspect, laser apparatus in accordance with the present invention comprises a plurality of diode-laser emitters mounted on a carrier. Each of the emitters has an emitter width and has a slow-axis parallel to the emitter width. The emitters are arranged in a plurality of groups thereof. Each of the groups includes one or more emitters. The plurality of emitters in all of the groups forms a longitudinal array with slow axes of the emitters aligned about collinear with each other and about parallel to the length of the array. The emitter groups are connected together in electrical series.

Connecting the groups together in electrical series reduces the electrical current required to drive the array in exchange for an increased voltage requirement. However, a current controlled high-voltage, low-current power supply is typically less complex and less costly than a current controlled low-voltage, high-current supply of the same electrical power.

In one preferred method for forming the inventive apparatus, the diode-laser bar is prepared by conventional methods and includes a plurality of spaced apart diode-laser emitters formed in epitaxial layers on an elongated electrically-conductive semiconductor substrate as discussed above. A carrier is prepared having a number of electrical contacts thereon, electrically isolated from each other. The diode-laser bar is bonded, epitaxial-layer side down, to the electrical contacts of the carrier and is then cut transversely into a number of sections corresponding to the number of electrical contacts of the carrier. Each of the diode-laser bar sections includes one or more of the plurality of emitters and has an epitaxial-layer side and a substrate side. The diode-laser bar sections are cut relative to the electrical contacts of the carrier such that the diode-laser bar sections are electrically isolated from each other. The diode-laser bar sections are then electrically connected together in series by electrically connecting the substrate side of one of the diode-laser bar sections to the epitaxial-layer side of an adjacent one of the diode-laser bar sections via the electrical contact associated with that adjacent section.

### BRIEF DESCRIPTION OF THE DRAWINGS

The accompanying drawings, which are incorporated in and constitute a part of the specification, schematically illustrate a preferred embodiment of the present invention, and together with the general description given above and the detailed description of the preferred embodiment given below, serve to explain principles of the present invention.

FIGS. 1A-E schematically illustrate steps of a preferred method in accordance with the present invention of making a series-connected diode-laser array, with the array being supported in sections on a thick dielectric layer.

FIG. 2 is a three-dimensional view schematically illustrating one preferred embodiment of a series connected diode-laser array in accordance with the present invention formed by the method of FIGS. 1A-E.

FIG. 2A is a three-dimensional view schematically illustrating another preferred embodiment of a series connected diode-laser array in accordance with the present invention similar to the array of FIG. 2, but wherein the sections are supported on a thin dielectric layer that is supported in turn on a metal heat sink.

### DETAILED DESCRIPTION OF THE INVENTION

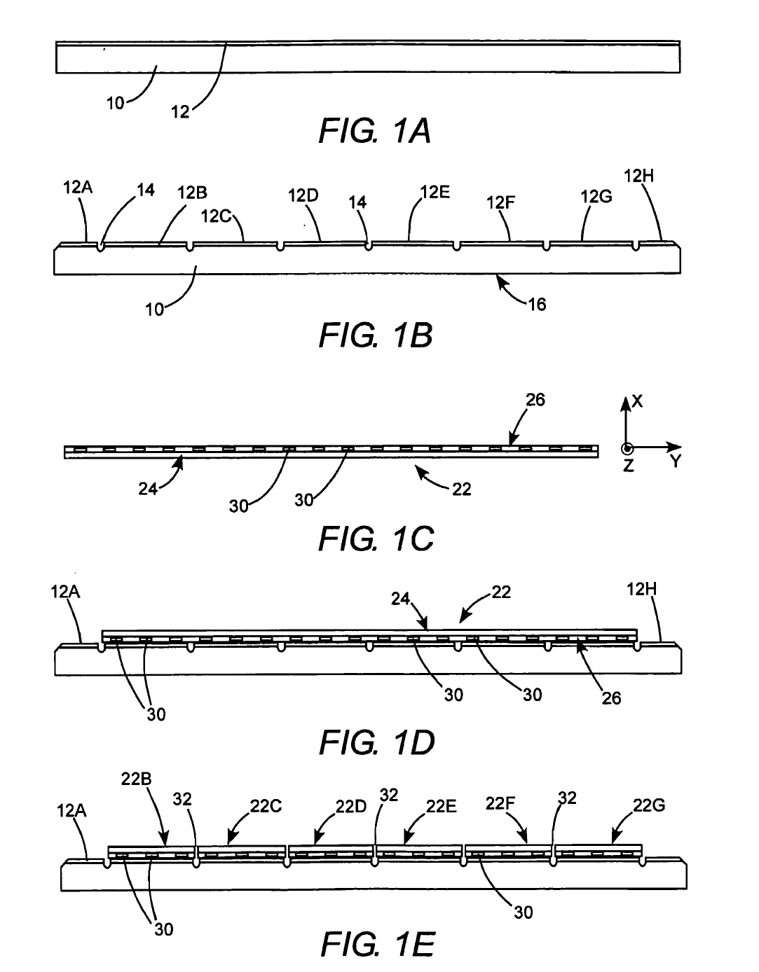

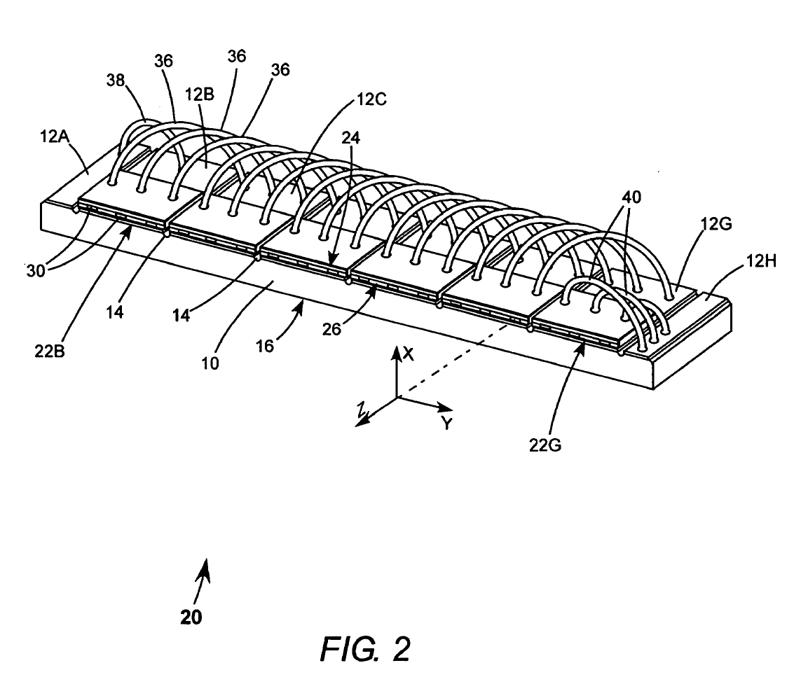

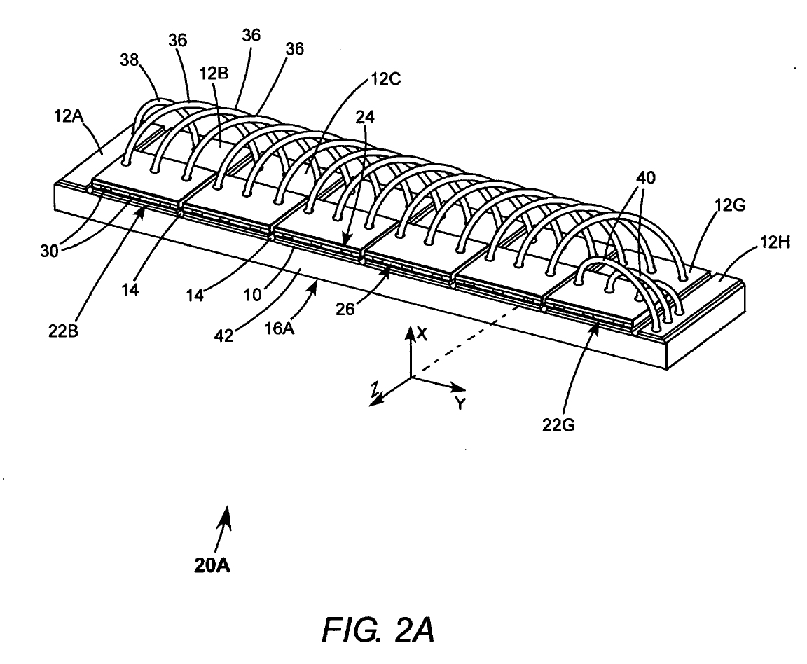

Referring now to the drawings, wherein like components are designated by like reference numerals, FIG. 1A, FIG. 1B, FIG. 1C, FIG. 1D, and FIG. 1E schematically illustrate steps of a preferred method of making a series-connected diode-laser array in accordance with the present invention. Further detail of a preferred embodiment 20 of the array formed by the method is depicted in the three-dimensional view of FIG. 2.

One step in the method is to form a diode-laser bar carrier having a set of electrical contacts which are electrically isolated from each other. In a preferred embodiment of the inventive method illustrated by FIGS. 1A-E, a layer 10 of a thermally conductive dielectric material has a metal layer 12 formed thereon. A series of parallel grooves 14 is cut into the metallized layer and extend through the metallization into the dielectric layer (see FIG. 1B and FIG. 2) such that the metal layer is divided into a group of metal pads 12A-H that are electrically isolated from each other. The groove spacing is equal to or greater than the center-to-center spacing of emitters in the diode-laser bar.

The grooving operation forms the required carrier, designated by the general numeral 16, with pads 12A-H providing the electrical contacts, electrically isolated from each other by the grooves extending into the dielectric layer. In this example, the dielectric layer is assumed to be rigid. Such a layer may be fabricated, for example, from a thermally conductive ceramic material such as aluminum nitride or beryllia (beryllium oxide). The electrical contacts may comprise, for example, a layer of highly electrically conductive material such as copper and a bonding layer of solder material such as a gold-tin (AuSn) solder. The surface of the bonding layer should be relatively flat and smooth to facilitate the subsequent bonding of a diode-laser bar.

Those skilled in the art will recognize that a carrier may be formed from a highly thermally conductive material such as copper having a relatively thin (not rigid or self supporting) dielectric layer 16 of a material such as diamond thereon, with the set of electrical contacts 12A-H formed on the electrically insulating layer. The isolated contacts can be formed by, for example, separately plating individual contacts on a carrier or by forming a large, single contact and etching patterns to form isolated contacts, or by forming a large, single contact and removing the conductive material from the region between adjacent contacts by means of mechanical sawing or laser ablation to form adjacent isolated contacts. An example of such alternative carrier is described further herein below. The present description proceeds, however, using the example of carrier 16 depicted in FIG. 1B.

FIG. 1C schematically illustrates an example 22 of a conventional diode-laser bar. The diode-laser bar includes an elongated semiconductor substrate 24 having a group 26 of epitaxially grown layers thereon having a plurality of diode-laser emitters therein. In this example, diode-laser bar 22 is assumed to have eighteen emitters. The emitters are defined, inter alia, by a “stripe” electrode (not shown) formed on the epitaxial layers. The emitters are identified in the drawings by emitting-apertures 30 thereof. Those skilled in the art will recognize that the term “aperture”, here, refers to an optical rather than a physical aperture. These rectangular emitting-apertures may also be designated emitting-regions. The emitting-regions or apertures are aligned substantially collinear with each other in the slow-axis of the emitters. The slow- and fast-axes are designated the Y- and X-axes, respectively, in FIG. 1C and FIG. 2. The propagation axis is the Z-axis.

The term “substantially-collinear”, referring to the alignment of the emitting regions, acknowledges that exact collinear alignment of the emitting-apertures in a diode laser bar is rarely ever achieved. Even with the most careful manufacturing techniques, the emitting apertures are usually gradually misaligned along the length of the bar with a height difference in the fast-axis (here the X-axis) of a few microns between end ones of the apertures and a central one of the apertures. This misalignment is due to stresses developed in the epitaxial-layer growing process and is whimsically termed “smile” by practitioners of the art. Smile makes fast-axis collimation of beams from all emitters with a single cylindrical lens element (a collimation method preferred by practitioners of the art) difficult.

A next step in the inventive diode-laser-array forming method is to bond diode-laser bar 22, with the epitaxial layers (epitaxial-layer side) down, to the grooved metallized surface of substrate or carrier 16 (see FIG. 1D). This is preferably done by soldering, using solders and techniques well known in the art. Having the metallized surface of the carrier as flat and smooth as possible before grooves 14 are cut therein minimizes the possibility of additional misalignment of emitters 30 of the diode-laser bar when the bar is soldered to the carrier.

Referring now to FIG. 1E with continuing reference to FIG. 2, after diode-laser bar 22 is soldered to carrier 16 a series of parallel transverse cuts 32 are made through diode-laser bar 22. The parallel cuts are aligned with grooves 14 in carrier 16. These cuts divide or separate the diode-laser bar into six sections, designated sections 22B-G in FIG. 1E, each thereof including three emitters 30, and with the epitaxial-layer side of the diode-laser bar portions in contact with electrodes or contact pads 12B-G, respectively. As the diode-laser bar, and accordingly sections 22B-G thereof have a width less than the pad width (here the width of carrier 16) a portion of each pad remains exposed (see FIG. 2) providing a means of making an electrical contact to the epitaxial-layer side 26 of the corresponding diode-laser bar section.

Cuts 32 through the diode-laser bar may be made by sawing or by localized laser ablation of the diode bar. The separation may also be performed by masking and etching using, for example, reactive ion etching. Whatever method is selected the separation or division of the diode-laser bar to form the groups of emitters should not significantly change the relative alignment of the emitting themselves.

Continuing with reference to FIG. 2, after the diode-laser bar has been separated into sections, the sections (emitter groups) are electrically connected in series. One preferred method of making the electrical connections is to use conventional wire bonding equipment to the substrate side of one diode-laser bar section (emitter group) with the contact pad and accordingly with the epitaxial-layer side of an adjacent diode-laser bar section (emitter group). This method of connection is depicted in FIG. 2 by wires 36 connecting the substrate side of section 22B of the diode-laser bar with contact pad 12C, i.e., with the epitaxial-layer side of diode-laser bar section 22C. Other adjacent sections are similarly connected. Pads 12A and 12H in this example are used as contact pads to which a power supply can be connected. Wires 38 (only one shown) connect contact pad 12A to contact pad 12B. Wires 40 connect substrate portion 24 of diode-laser bar section 22G to contact pad 12H. Clearly when there is more than one emitter in a diode-laser bar section the emitters in this section (emitter group) are electrically connected with each other in parallel.

It should be noted here that the number of wires per diode-laser bar section need not correspond to the number of emitters per diode-laser bar section. Those skilled in the art will recognize that the number of wires can be selected according to the total current drawn by the array and the current carrying capacity of individual wires, among other factors.

Other means of forming electrical connections to the diode groups are anticipated, including soldering of flexible circuit elements to the contact pads and the diode-laser top electrodes or the further bonding of a second insulating carrier assembly to the substrate side of the diode-laser bar. This second insulating carrier could have a matching set of isolated electrical contacts to make individual electrical connection to the electrically isolated groups of diode-laser emitters. Electrical connections could then be made to these electrical contacts by, for example, soldering of flexible circuit elements.

An alternative process for forming electrically isolated groups of emitters includes the step of etching grooves in the epitaxial layers 26 of the diode-laser bars, at least through the epitaxial layers and possibly partially into the substrate portion 24. This etching is preferably done at the wafer stage before the wafer is cleaved into individual diode-laser bars. The grooves would be generally in the region where the diode groups will be separated after the diode-laser bar is attached to the metallized grooved layer (carrier 16). These etched grooves are preferably made somewhat wider than the saw, laser-beam, or other cut is later used to separate the diode-laser bar into sections. In this way the cut-edge of the substrate portion 24 of the diode-laser, which is prone to mechanical damage and chipping from the saw or laser cut, is removed from the edge of the epitaxial layers 26 of the diode-laser. This step will tend to reduce any tendency for mechanical defects to propagate through the epitaxial layers to the region of the optical emitters, thus tending to improve the lifetime or reliability of the assembled diode-laser array. Those skilled in the art may devise other methods of separating the diode-laser bar into electrically isolated sections without departing from the spirit and scope of the present invention.

FIG. 2A schematically illustrates a variation 20A of diode-laser array 20 of FIG. 2. In diode-laser array 20A, dielectric layer 10 of carrier 16A is not self-supporting but is a relatively thin layer, for example having a thickness between about 1 μm and about 500 μm, supported on a metal heat sink 42. The heat sink may be water cooled. In one example of such a heat-sink, the heat-sink could be made from aluminum and the dielectric layer could be an anodic aluminum-oxide layer formed on the heat-sink.

Regarding the number of emitters in the diode-laser bar sections or emitter groups, clearly the lowest operating current for the inventive array, for any total number of emitters, will be achieved when there is only one emitter per diode-laser bar section. For eighteen emitters having characteristics exemplified above this would be a current of about 2.5 A from a supply voltage of about 32.5 V. Three emitters per bar would require a current of about 7.5 A at a supply voltage of about 11 V, and so on.

Providing one emitter per diode-laser bar section, however, would require the greatest number of grooves and cuts and may involve a lower manufacturing yield than might be experienced with a greater number of emitters per diode-laser bar section. The choice of the number of emitters per bar will ultimately depend on factors such as the cost and availability of current controlled power supplies and the cost and yield of cutting and grooving operations. It is not necessary that the number of emitters per diode-laser bar section be the same. By way of example, a diode-laser bar having a total of nineteen emitters may be divided into five diode-laser bar sections each having three emitters, and two diode-laser bar sections each having two emitters.

A particular advantage of having the individual emitters or groups of emitters arranged with a series electrical connection is an enhanced ability to modulate the electrical drive to the diode elements. With a parallel electrical connection to the diodes, about 50 amps of current would need to be varied (modulated) to change the light output of the diode bar. While this is possible over a longer time scale, for example several milliseconds (ms), by controlling the power supply output, it is difficult or expensive to pulse this current over a short time scale, such as about one microsecond (its). With a series connection, it is relatively straightforward to switch the lower currents, say either 2.5 amps or 7.5 amps, in such a short time. Potential applications such as modulating pump-light to diode-pumped lasers would be enhanced by the ability to rapidly modulate the pump-light to these lasers.

In summary, the present invention is described above in terms of a preferred and other embodiments. The invention is not limited, however, to the embodiments described and depicted. Rather, the invention is limited only by the claims appended hereto.

1. Optical apparatus comprising:
a carrier;
a plurality of diode-laser emitters mounted on the carrier, each of the emitters having an emitter width and having a slow-axis parallel to the emitter width;
the emitters being arranged in a plurality of groups thereof, each of the groups including one or more of the plurality of emitters, with the plurality of emitters forming a longitudinal array, with slow-axes of the emitters aligned about collinear with each other and about parallel to the length of the array; and
wherein the emitter-groups are connected together in electrical series.

2. The apparatus of claim 1, wherein each of the groups includes the same number of emitters.

3. The apparatus of claim 1, wherein there is a total of 18 emitters in the plurality thereof arranged in six groups with each group having 3 emitters.

4. The apparatus of claim 1, wherein there is a total of 19 emitters in the plurality thereof arranged in five groups of 3 emitters and two groups of two emitters.

5. The apparatus of claim 1, wherein the carrier includes a plurality of mounting sections electrically isolated from each other each carrier section including a dielectric layer surmounted by a metal layer.

6. The apparatus of claim 5, wherein each group of diode-laser emitters includes an epitaxial layer portion on a substrate portion, wherein the epitaxial layer portion of each group is electrically connected to the metal layer of the corresponding carrier section, wherein the metal layer has a width greater width than the emitter group thereon, an wherein the emitter groups are electrically connected in series by electrical connections from the substrate portion of one emitter group to the epitaxial layer portion of an adjacent group via the metal layer to which the epitaxial layer group is electrically connected.

7. The apparatus of claim 5, wherein the dielectric layer of the carrier sections is common to all sections and the metal layer of each of the carrier sections is electrically isolated from the metal layer of any adjacent carrier sections.

8. Optical apparatus, comprising:
an electrically insulating carrier including a dielectric layer having a plurality of electrical contacts thereon electrically isolated from each other;
a plurality of diode-laser emitters each of the emitters having an emitter width and having a slow-axis parallel to the emitter width, the emitters being arranged in a plurality of groups thereof, each of the groups including one or more of the plurality of emitters and having an epitaxial-layer side and a substrate side;
each of the emitter groups being mounted with the epitaxial-layer side thereof electrically connected to a corresponding one of the electrical contacts and with the plurality of emitters forming a longitudinal array thereof, with slow-axes of the emitters aligned about collinear with each other and about parallel to the length of the array; and
wherein each of the emitter groups has a width less than the width of the corresponding one of the electrical contacts on which the emitter group is mounted and the emitter groups are electrically connected in series by electrical connections between the substrate side of one emitter group and the electrical contact on which another of the emitter groups is mounted.

9. The apparatus of claim 8, wherein the substrate side of each of all but one of the emitter groups is electrically connected to the electrical contact on which an adjacent emitter group is mounted.

10. The apparatus of claim 8, wherein the electrical connection between the substrate side of one emitter group and the electrical contact on which an adjacent emitter group is mounted is formed by one or more wires

11. The apparatus of claim 8, wherein each of the emitter groups includes the same number of emitters.

12. The apparatus of claim 8, wherein there is a total of eighteen emitters in the plurality thereof arranged in six emitter groups with each emitter group having three emitters.

13. The apparatus of claim 1, wherein there is a total of nineteen emitters in the plurality thereof arranged in five groups of three emitters and two groups of two emitters.

14-16. (canceled)
